(19) United States
(12) Patent Application Publication
(10) Pub. No.: US 2013/0224400 A1
(43) Pub. Date: Aug. 29, 2013

(54) APPARATUS FOR TREATING AN OBJECT, MORE PARTICULARLY THE SURFACE OF AN OBJECT MADE OF POLYMER

(71) Applicants: Alexis Chenet, Asnieres sur seine (FR); Frédéric Moret, Le Pecq (FR); Marc Brassier, Le Perreux sur Marne (FR)

(72) Inventors: Alexis Chenet, Asnieres sur seine (FR); Frédéric Moret, Le Pecq (FR); Marc Brassier, Le Perreux sur Marne (FR)

(73) Assignee: VALEO VISION, Bobigny Cedex (FR)

(21) Appl. No.: 13/825,067

(22) PCT Filed: Sep. 19, 2011
(86) PCT No.: PCT/EP2011/066193

§ 371 Date: May 10, 2013

(30) Foreign Application Priority Data
Sep. 20, 2010 (FR) 1057509

(51) Int. Cl. C23C 16/48; C23C 14/56

(52) U.S. Cl. CPC C23C 16/486; C23C 14/56
USPC 427/585; 204/298.04; 118/723 FI; 118/723 MP; 204/192.11

(57) ABSTRACT

An apparatus for treating an object, for example an object made of polymer for a light or headlamp of an automotive vehicle, comprises a vacuum chamber in which the object is intended to be placed; means for placing the chamber under vacuum; and ion bombardment means intended for treating the object, comprising an ion generator and at least one ion applicator intended to emit an ion beam. This apparatus comprises, in addition: a first airlock; means for selectively placing the vacuum chamber in communication with the first airlock and means for placing the first airlock under vacuum. The ion bombardment means are arranged outside of the vacuum chamber. The ion applicator is housed in the first airlock.

### CROSS-REFERENCE TO RELATED APPLICATIONS

This application is the U.S. National Phase application of PCT/EP2011/066193 filed Sep. 19, 2011, which claims priority to French Application No. 1057509 filed Sep. 20, 2010, which applications are incorporated herein by reference and made a part hereof.

### BACKGROUND OF THE INVENTION

1. Field of the Invention

The present invention relates to the field of object treatment, and more particularly to the treatment of the surface of an object made of polymer.

2. Description of the Related Art

An apparatus for treating an object is already known from the prior art, notably from FR-A-2 899 242, this apparatus comprising ion bombardment means intended for treating the object.

The ion bombardment means notably allow ions to be incorporated into the object in order to treat its surface, notably so as to influence the mechanical properties of this surface (hardness, tribology, etc.).

Ion bombardment means, such as those described in FR-A-2 899 242, conventionally comprise means acting as an ion generator and means acting as an ion applicator.

The ion applicator conventionally comprises means chosen, for example, from electrostatic lenses for shaping the ion beam, a diaphragm, a shutter, a collimator, an ion-beam analyzer and an ion-beam controller.

The ion generator conventionally comprises means chosen, for example, from an ionization chamber, an electron cyclotron resonance ion source, an ion accelerator and an ion separator.

Ion bombardment is conventionally carried out under vacuum. Thus FR-A-2 899 242 suggests housing all of the ion bombardment means (ion generator and ion applicator) and the object to be treated in a vacuum chamber. Means for generating a vacuum are connected to this chamber. These means for generating a vacuum must allow a relatively high vacuum to be obtained in the chamber, for example about 10⁻² mbar to 10⁻⁶ mbar.

Treatment of a large number of objects involves carrying out many operations of loading/unloading the chamber. However, each loading/unloading operation involves bringing the chamber to atmosphere. It is therefore necessary to recreate appropriate vacuum conditions in the chamber and the ion application means each time after this chamber is brought to atmosphere.

### SUMMARY OF THE INVENTION

The aim of the invention is notably to optimize the time taken and the energy necessary to restore appropriate vacuum conditions in the chamber and the ion application means after each operation of loading/unloading this chamber.

For this purpose, one subject of the invention is an apparatus for treating an object, of the type comprising:

a vacuum chamber in which the object is intended to be placed;

means for placing the chamber under vacuum; and

ion bombardment means intended for treating the object, comprising an ion generator and at least one ion applicator intended to emit an ion beam;

wherein it comprises, in addition:

a first airlock;

means for selectively placing the vacuum chamber in communication with the first airlock; and

means for placing the first airlock under vacuum,

the ion bombardment means being arranged outside of the vacuum chamber, and the ion applicator being housed in the first airlock.

The selective communication means between the vacuum chamber and the first airlock make it possible to selectively place the vacuum chamber and the first airlock in communication or to isolate the vacuum chamber and the first airlock.

During operations of loading/unloading the vacuum chamber, the airlock will possibly be isolated from this chamber, to the point that it will possibly remain under vacuum, whereas the chamber is returned to atmosphere.

During a new ion bombardment operation, it will be enough to recreate appropriate vacuum conditions in the chamber, before again placing this chamber in communication with the airlock, which will have preserved a vacuum level near that desired in the chamber.

Thus, during operations of loading/unloading the vacuum chamber, the immediate environment of the applicator and of any member of the generator able to communicate pressure with the applicator is kept at a vacuum level quite near that desired in the chamber for treating an object. This allows the time and energy necessary to return the chamber and the ion application means to appropriate vacuum conditions after each operation of loading/unloading this chamber to be optimized.

Moreover, since the ion bombardment means are arranged outside of the vacuum chamber, the volume available in the chamber may essentially be dedicated to accommodating objects to be treated.

According to other optional features of various embodiments of the apparatus according to the invention:

the ion applicator comprises means chosen from electrostatic lenses for shaping the ion beam, a diaphragm, a shutter, a collimator, an ion-beam analyzer and an ion-beam controller;

the ion generator comprises means chosen from an ionization chamber, an electron cyclotron resonance ion source, an ion accelerator, and an ion separator;

the means for placing the chamber under vacuum comprise a primary pumping assembly comprising a rotary mechanical pump in series with a Roots blower;

the means for placing the chamber under vacuum comprise a secondary pumping assembly comprising at least one pump chosen from a diffusion pump or a turbomolecular pump;

the ion bombardment means comprise a plurality of ion applicators. The ion bombardment means may also comprise means for adjusting the position of each applicator, means for adjusting the angle of the ion beam emitted by each applicator, and means for controlling these means for adjusting position and these means for adjusting angle;

the apparatus comprises:
a second airlock;
means for selectively placing the vacuum chamber in communication with the second airlock;
means for placing the second airlock under vacuum; and
vacuum sputtering or vacuum evaporation PVD deposition means comprising:
   means housed in the second airlock, notably comprising a sputtering target or a material to be evaporated with means for heating this material; and
   means for injecting gas into the vacuum chamber, notably a gas intended to create a plasma, for example argon and/or a reactive gas, for example oxygen or nitrogen;

the apparatus comprises:
at least one electrode intended to be brought to a potential different from that of the object to be treated; and
means for injecting, into the vacuum chamber, gas intended to create a plasma;
the means for placing the chamber under vacuum and the means for placing each airlock under vacuum comprise communal pumping means;
the apparatus comprises a planetary carrier fitted in the vacuum chamber so as to be able to rotate about a virtual axis relative to this chamber, this planetary carrier preferably bearing a plurality of satellite supports for supporting objects, each satellite support being fitted so as to be able to rotate about a virtual axis relative to plant planetary carrier;
the vacuum chamber, called the ion bombardment chamber, is housed in another vacuum chamber, called container, the means for placing the ion bombardment chamber under vacuum comprising means for indirectly generating a vacuum, connected to this ion bombardment chamber via the container chamber and, preferably, means for generating a vacuum in the ion bombardment chamber directly;

the apparatus comprises:
at least one PVD deposition chamber housed in the container chamber;
a moveable support, intended to carry the object to be treated, which support can be moved between a position for accommodating the object in the ion bombardment chamber and a position for accommodating the object in the PVD deposition chamber;
means for placing the PVD deposition chamber under vacuum;
a second airlock;
means for selectively placing the PVD deposition chamber and the second airlock in communication;
means for placing the second airlock under vacuum; and
vacuum sputtering or vacuum evaporation PVD deposition means,

comprising:
means housed in the second airlock, notably comprising a sputtering target or a material to be evaporated with means for heating this material; and
means for injecting gas into the vacuum chamber, notably a gas intended to create a plasma, for example argon and/or a reactive gas, for example oxygen or nitrogen;

the apparatus comprises:
at least one PECVD deposition chamber, housed in the container chamber, the moveable support also being able to move into a position for accommodating the object in the PECVD deposition chamber;
means for placing the PECVD deposition chamber under vacuum; and
plasma-enhanced PECVD deposition means, comprising:
   at least one electrode intended to be brought to a different potential from that of the object to be treated, and
   means for injecting, into the vacuum chamber, gas intended

to create a plasma;

the apparatus comprises:
at least one loading/unloading chamber for loading/unloading objects, the loading/unloading chamber being housed in the container chamber, the moveable support also being able to move into a receiving/presenting position in the loading/unloading chamber; and
means for placing the loading/unloading chamber under vacuum;
the apparatus comprises a support fitted so as to oscillate about at least one axis, preferably about two substantially perpendicular axes, and bearing the ion applicator and at least part of the ion generator so as to allow a beam to be formed that oscillates about at least one axis, preferably about two substantially perpendicular axes.

In the invention, the gas intended for creating a plasma may for example be helium, neon, krypton, argon, xenon, dioxygen or dinitrogen, whether alone or in mixtures.

Another subject of the invention is also the use of an apparatus according to the invention for the treatment of an object made of polymer.

Various types of objects can be treated according to the invention. In particular the object may have an aesthetic function and form, for example, a mask or a trim for a light or headlamp of a vehicle. The object may also have a mechanical function, for example forming a plate or casing, notably a plate or casing for a light or headlamp of a vehicle, the plate or casing being intended to bear optical, mechanical or electrical elements. The object may have an optical function and form, for example, a reflector or a screen participating in the shaping of a beam of light, notably for a light or headlamp of a vehicle. The object may have a chemical function and form, for example, a detector, notably for a light or headlamp of a vehicle. The object may have an electrical function and form, for example, an electrical insulator, notably for a light or headlamp of a vehicle. The object may have a thermal function and form, for example, a radiator, notably for a light or headlamp of a vehicle.

The invention will be better understood on reading the following description, given merely by way of example and with regard to the appended drawings, in which:

### BRIEF DESCRIPTION OF THE ACCOMPANYING DRAWINGS

FIGS. 1 to 3 are schematic views of an apparatus for treating an object, according to a first embodiment of the invention, this apparatus being shown, respectively, in three different operating configurations;

FIG. 4 is a schematic view of an apparatus for treating an object according to a second embodiment of the invention;

FIG. 5 is a schematic view of an apparatus for treating an object, according to a third embodiment of the invention; and

FIG. 6 is a schematic view of an apparatus for treating an object, according to a fourth embodiment of the invention.

### DETAILED DESCRIPTION OF THE PREFERRED EMBODIMENTS

FIGS. 1 to 3 show an apparatus for treating an object according to a first embodiment of the invention. This apparatus is denoted by the general reference 10.

The apparatus 10 is more particularly intended to treat a surface of an object made of polymer for an automotive vehicle, more particularly a light or a headlamp of this vehicle.

Various types of objects may be treated. In particular, the object may have an aesthetic function and form, for example, a mask or a trim for a vehicle light or headlamp. The object may also form a plate or a casing for a light or headlamp of a vehicle, the plate or casing being intended to bear optical, mechanical or electrical elements. The object may have an optical function and form, for example, a reflector or a screen participating in the shaping of a beam of light.

The apparatus 10 is intended to treat the surface of the object, notably to deposit thin layers thereon, and to influence the mechanical properties of the surface of the object.

The apparatus 10 comprises a vacuum chamber 12 in which at least one object is intended to be placed. This chamber 12 comprises a body 14 and a lid 16 intended to allow access to the interior of the chamber 12.

In the first embodiment of the invention, a planetary carrier 18 is fitted so as to be able to rotate in the chamber 12 about a virtual axis XP relative to this chamber. Moreover, the planetary carrier 18 bears a plurality of satellite supports 20, for example being six in number, each of which is intended to carry at least one object 22 to be treated. Each satellite support 20 is fitted so as to be able to rotate about a virtual axis XF relative to the planetary carrier 18.

The chamber 12 is capable of being placed under a vacuum using means 24 comprising a primary pumping assembly 26, allowing a vacuum of about 10⁻² mbar to be obtained and, preferably, a secondary pumping assembly 28, allowing a vacuum of between about 10⁻² and 10⁻⁶ mbar to be obtained.

In the example shown, the primary pumping assembly 26 comprises a mechanical rotary pump 30 connected in series with a Roots blower 32. The mechanical rotary pump 30 allows a vacuum of about 10⁻¹ mbar to be obtained. This vacuum level then allows the Roots blower 32 to be started. The latter allows a vacuum of about 10⁻² mbar to be obtained.

Moreover, in the example shown in FIGS. 1 to 3, the secondary pumping assembly 28 comprises a pump allowing a vacuum of between about 10⁻² and 10⁻⁶ mbar to be obtained, for example a diffusion pump 34.

The apparatus 10 also comprises a first airlock 36 and a second airlock 38. A first door 40 and a second door 42 form means for selectively placing the vacuum chamber 12 in communication with the first airlock 36 and the second airlock 38, respectively. Each airlock 36, 38 is connected to vacuum generating means.

Preferably, as FIGS. 1 to 3 show, the means for placing the chamber 12 under vacuum and the means for placing each airlock 36, 38 under vacuum comprise communal pumping means, namely the primary pumping assembly 26 and the secondary pumping assembly 28 described above. Thus, FIGS. 1 to 3 show pipes C and valves V allowing the chamber 12 and the airlocks 36, 38 to be selectively connected, depending on the desired treatment conditions, to the primary pumping assembly 26 and the secondary pumping assembly 28.

The apparatus 10 comprises ion bombardment means 44 intended to treat the objects 22 contained in the chamber 12. These means 44 comprise an ion generator 46 and an ion applicator 48 that is intended to emit an ion beam.

The ion bombardment means 44 are arranged outside of the chamber 12. More particularly, it will be noted that the ion applicator 48 is housed in the first airlock 36.

Conventionally, the ion applicator 48 comprises means chosen from electrostatic lenses for shaping the ion beam, a diaphragm, a shutter for isolating the beam (notably a Faraday cage), a collimator, an ion-beam analyzer and an ion-beam controller.

Generally, the ion applicator 48 is set up so that the surface of an object 22 can be treated without the ion beam emitted needing to be focused, that is, a large depth of field is used.

As a variant, the ion bombardment means 44 may comprise a plurality of ion applicators 48, means for adjusting the position of each applicator 48, means for adjusting the angle of the ion beam emitted by each applicator 48, and means for controlling these means for adjusting position and these means for adjusting angle.

The means for adjusting position and means for adjusting angle allow the surfaces of objects of various forms to be rapidly and effectively treated, notably skewed surfaces.

The means for controlling the means for adjusting position and angle comprise, for example, software means called PLCs (programmable logic controllers).

Moreover, the ion generator 46 comprises, in the conventional manner, means chosen from an ionization chamber, an electron cyclotron resonance ion source 50, an ion accelerator 52 and an ion separator.

It will be noted that among the means mentioned above capable of forming the ion generator 46 and the ion applicator 48, all are not essential, depending on the ions used. Thus, for example, for ions obtained from helium gas generally neither an ion separator nor an ion-beam analyzer, nor an ion-beam controller will be used.

The apparatus 10 also comprises physical vapor deposition (PVD) means 54.

Preferably, the PVD deposition means 54 are conventional vacuum sputter deposition means or vacuum evaporation means. These deposition means 54 notably comprise means 56 housed in the second airlock 38 and conventional means 58 for injecting a gas into the vacuum chamber 12.

PVD deposition for example allows a very thin metal layer to be produced on the surface of the objects 22, this thin metal layer notably being between 50 and 100 nm in thickness.

In the case of PVD deposition by vacuum sputtering, the means 56 housed in the second airlock 38 comprise a conventional sputtering target. The means 58 are capable of injecting a gas intended to create a plasma, for example argon, and/or a reactive gas, for example oxygen or nitrogen.

The supports of the objects 22, more particularly the satellite supports 20, form anodes allowing an electric discharge, for generation of the plasma, to be created between these anodes and the target 56, which acts as a cathode.

In the case of PVD deposition by vacuum evaporation, the means 56 housed in the second airlock 38 comprise a material to be evaporated and means for heating this material. The means 58 are capable of injecting a reactive gas, for example oxygen or nitrogen.

Finally, the apparatus 12 comprises chemical vapor deposition (CVD) means 60.

Preferably, the CVD deposition means 60 are conventional plasma-enhanced means. Plasma-enhanced CVD deposition is commonly referred to by its acronym PECVD.

These PECVD deposition means 60 comprise at least one electrode 62, for example two electrodes 62 as shown in FIGS. 1 to 3, intended to be brought to a potential different from that of the objects to be treated 22. The PECVD deposition means 60 also comprise conventional means 64 for injecting gas into the vacuum chamber, this gas being intended for creating a plasma.

PECVD deposition allows, for example, a very thin protective layer to be produced on the surface of the objects 22, this layer notably being between 20 and 100 nm in thickness and, for example, made of a polysiloxane material that is mostly or completely inorganic. This protective layer may notably cover a metal layer produced by PVD deposition.

The supports of the objects 22, in particular the satellite supports 20, form electrodes brought to a different potential from that of the electrodes 62. The electrodes of different, generally opposite, potentials allow an electric discharge to be created and the plasma to be formed. Conventionally, the electric discharge is a DC discharge, or one formed by means of a high frequency, for example radio or microwave frequency.

The apparatus 10 according to the invention makes it possible to treat the objects 22 with various treatments—namely ion bombardment, PVD deposition and PECVD deposition—in any order or even simultaneously without having to unload the objects 22 contained in the vacuum chamber 12.

In addition, the ion bombardment means 44, arranged outside of the chamber 12, do not take up space inside this chamber 12, thereby ensuring a relatively large volume is available in this chamber 12 to accommodate the objects 22.

### Example 1 Sequence for the Treatment of Objects 22

1. The objects 22 are loaded into the vacuum chamber 12.

2. The vacuum levels required in the chamber 12 and the airlocks 36, 38 are obtained using primary pumping and secondary pumping assemblies 26, 28.

3. The door 40 is opened, placing the first airlock 36 in communication with the chamber 12.

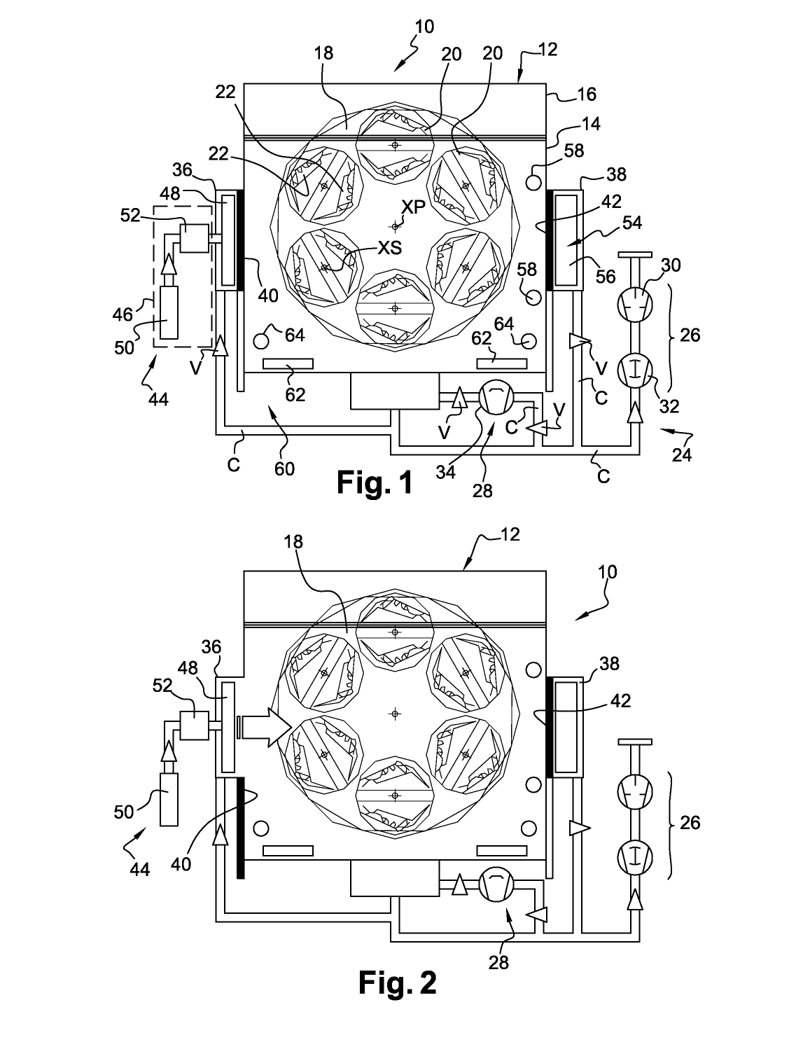

4. The objects 22 are bombarded with ions (see FIG. 2).

5. The door 42 is opened, placing the second airlock 38 in communication with the vacuum chamber 12.

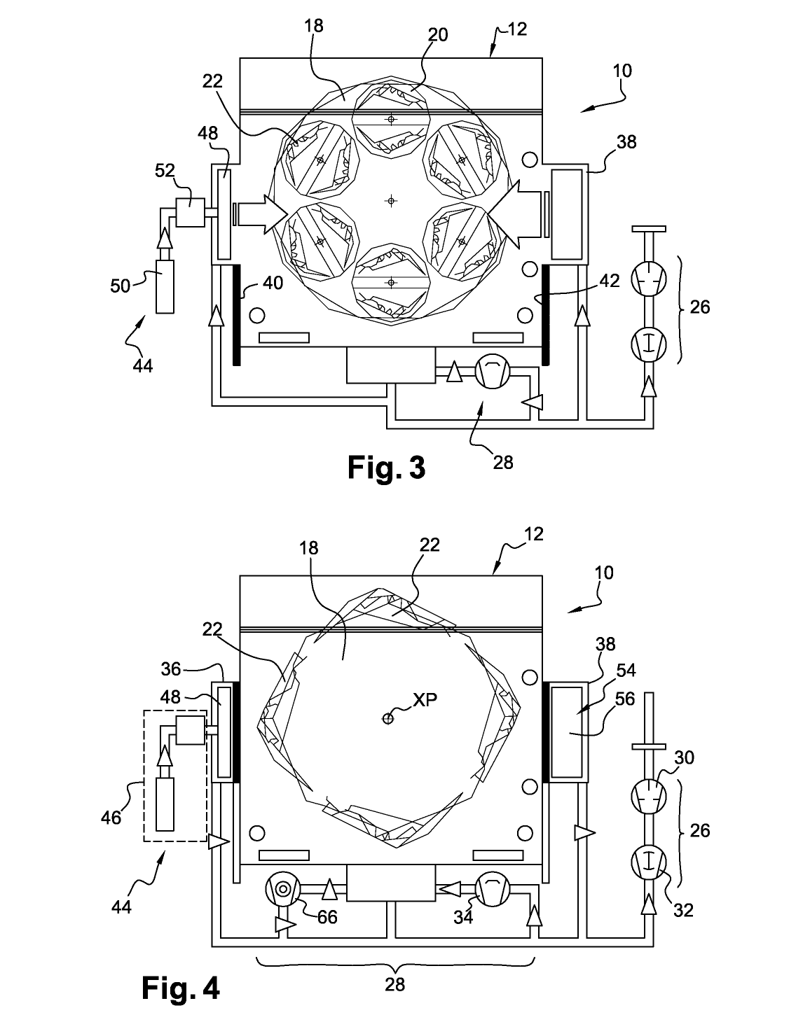

6. Simultaneously, ion bombardment and PVD deposition are carried out (see FIG. 3).

7. The door 40 is closed so as to isolate the first airlock 36 from the vacuum chamber 12.

8. A PVD deposition is carried out with injection of a reactive gas (reactive PVD). Thus, as is known per se, during the PVD deposition, the reactive gas is injected, which gas reacts with the metal vapor or metal oxide vapor (for example the reactive nitrogen gas reacts in order to form nitrides or the reactive oxygen gas reacts to form oxides).

9. The treated objects 22 are unloaded.

In general, each ion bombardment, PVD deposition, or PECVD deposition step is carried out under vacuum conditions that are specific to this step. Thus, depending on the circumstances, between certain of the above steps, the vacuum level in the chamber 12 is adjusted by virtue of the primary pumping and secondary pumping assemblies 26, 28.

Likewise, the metal deposition steps (PVD) generally cause contamination. Thus, if required, a decontaminating purge of the chamber 12 may be carried out between two treatment steps.

It will be noted that, when ion bombardment is not desired, the door 40 isolating the first airlock 36 from the vacuum chamber 12, is closed, thereby allowing the vacuum level in the first airlock 36 to be preserved until a subsequent ion bombardment step.

It will also be noted that the invention allows various ion bombardment, PVD deposition, and PECVD deposition steps to be carried out while avoiding any contact of the objects 22 with the atmosphere between the treatment steps, and therefore any risk of exposing the objects 22 to dust in the atmosphere between treatment steps.

Other examples will be given below of sequences for the treatment of objects 22—only essential steps being mentioned.

### Example 2 Sequence for the Treatment of Objects 22

1. The objects 22 are loaded into the vacuum chamber 12.

2. A glow discharge plasma is struck.

3. An underlayer is produced on the objects 22 by PECVD.

4. The objects 22 are bombarded with ions.

5. PVD deposition is carried out on the objects 22.

6. An overlayer is produced on the objects 22 by PECVD.

### Example 3 Sequence for the Treatment of Objects 22

1. The objects 22 are loaded into the vacuum chamber 12.

2. The objects 22 are bombarded with ions.

3. PVD deposition is carried out on the objects 22.

4. An overlayer is produced on the objects 22 by PECVD.

### Example 4 Sequence for the Treatment of Objects 22

1. The objects 22 are loaded into the vacuum chamber 12.

2. The objects 22 are bombarded with ions.

3. PVD deposition is carried out on the objects 22.

4. An overlayer is produced on the objects 22 by PECVD.

5. The objects 22 are bombarded with ions.

### Example 5 Sequence for the Treatment of Objects 22

1. The objects 22 are loaded into the vacuum chamber 12.

2. The objects 22 are bombarded with ions.

3. PVD deposition is carried out on the objects 22.

4. The objects 22 are bombarded with ions.

5. An overlayer is produced on the objects 22 by PECVD.

FIGS. 4 to 6 show an apparatus 10 according to second to fourth embodiments of the invention, respectively. In these FIGS. 4 to 6, analogous elements to those in the preceding figures are denoted by identical references.

In the second embodiment of the apparatus 10 (see FIG. 4), the objects 22 are carried directly by the planetary carrier 18. Moreover, the secondary pumping assembly 28 comprises a turbomolecular pump 66, for example connected in parallel with the diffusion pump 34. The combination of these two pumps 34, 66 allows vacuum levels between about 10^{˜2} and 10⁻⁶ mbar to be obtained more easily.

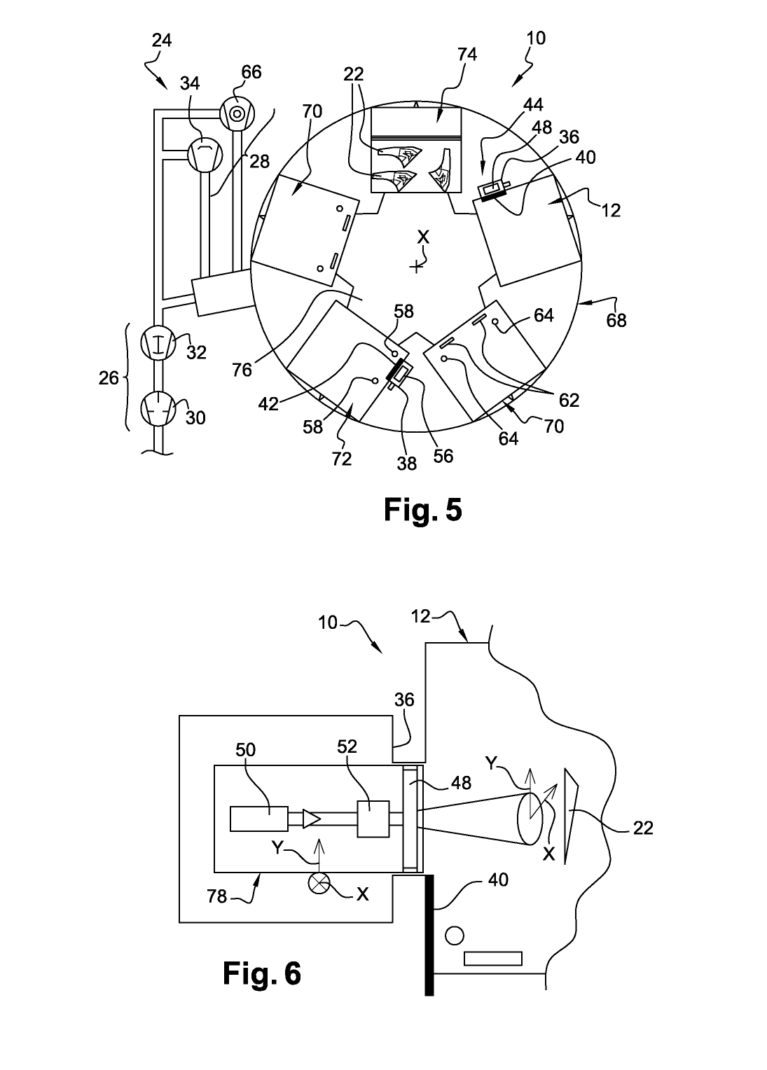

In the third embodiment of the apparatus 10 (see FIG. 5), the vacuum chamber 12 is dedicated only to ion bombardment, the PVD and PECVD depositions being carried out by other means that will be described below.

In the following, the vacuum chamber 12 will be called the ion bombardment chamber 12. The first door 40 forms means for selectively placing the ion bombardment chamber in communication with the first airlock 36, in which the ion applicator 48 is housed.

The ion bombardment chamber 12 is contained in another vacuum chamber 68, called the container chamber.

The means 24 for placing the chamber 12 under vacuum comprise, for example, primary and secondary pumping assemblies 26, 28 similar to those of the second embodiment of the invention. These primary and secondary pumping assemblies 26, 28 form means for indirectly placing the ion bombardment chamber 12 under vacuum because they are intended to be connected to this ion bombardment chamber 12 via the container chamber 68. Optionally, means for placing the ion bombardment chamber 12 under vacuum directly, may be provided.

The apparatus 10 according to the third embodiment of the invention comprises other vacuum chambers contained in the container chamber 68.

In the example shown in FIG. 5, the ion bombardment chamber 12 and the other vacuum chambers are arranged in a circle in the container chamber 68.

With reference to FIG. 5, and in a clockwise direction, the other vacuum chambers are:

a first PECVD deposition chamber 70;

a PVD deposition chamber 72;

a second PECVD deposition chamber 70; and

a chamber 74 for loading/unloading objects.

The apparatus 10 according to the third embodiment of the invention also comprises a moveable support 76 intended to carry the objects 22, and able to move, for example, about a virtual axis X relative to the container chamber 68, between various positions for accommodating the objects 22 in the various chambers 12, 70, 72 and 74.

As a variant, the various chambers 12, 70, 72 and 74 could be aligned, the moveable support 76 in this case being able to move in translation.

The PECVD deposition chambers 70, the PVD deposition chamber 72 and the loading/unloading chamber 74 are each connected to means for placing these chambers under vacuum, comprising, for example, primary and secondary pumping assemblies 26, 28, generating a vacuum in these chambers indirectly.

In contrast to the preceding embodiments, the second airlock 38 is intended to communicate with the PVD deposition chamber 72. Thus, the door 42 allows the PVD deposition chamber 72 to be selectively placed in communication with the second airlock 38.

The vacuum in the second airlock 38 is generated using means comprising, for example, primary and secondary pumping assemblies 26, 28 generating a vacuum in the second airlock 38 indirectly.

If required, the vacuum in the second airlock 38 may be generated using independent means.

The PVD deposition chamber 72 comprises conventional vacuum sputtering PVD deposition means comprising the sputtering target 56 housed in the second airlock 38. The PVD deposition means also comprise means 58 for injecting gas into the chamber 72, this gas, for example argon, being intended for creating a plasma.

Each PECVD deposition chamber 70 comprises plasma-enhanced PECVD deposition means comprising at least one electrode, for example the two electrodes 62, and means 64 for injecting gas intended for creating a plasma into the chamber 70.

The apparatus 10 according to the third embodiment of the invention allows the objects 22 to be treated, for example in the following way.

Firstly, the moveable support 76 is located in a position allowing objects 22 to be received. Next, the objects 22 are loaded onto the support 76. Next, the support 76 is moved from one chamber to another in sequences which may vary. Finally, the support 76 is placed in a position allowing the treated objects 22 to be presented in the chamber 74 in order to allow these objects to be unloaded.

In the fourth embodiment (see FIG. 6), the apparatus 10 comprises a support 78 that is fitted so as to oscillate, using conventional means, about at least one axis, preferably about two substantially perpendicular axes X, Y, as is shown in FIG. 6.

The support 78 bears the ion applicator 48, which for example comprises electrostatic lenses for shaping the ion beam and a shutter.

The support 78 also bears at least one part of the ion generator 46, for example the source 50 (or an ionization chamber) and the accelerator 52.

In this case, the airlock 36 contains the applicator 48 and optionally the support 78 and the elements of the generator 46 borne by this support 78.

The oscillations of the support 78 about the axes X, Y allow a beam to be formed that oscillates about two substantially perpendicular axes, i.e. the ion beam forms an oscillation cone. This oscillation cone allows a relatively large area of the object 22 housed in the chamber 12 to be treated.

While the system, apparatus, process and method herein described constitute preferred embodiments of this invention, it is to be understood that the invention is not limited to this precise system, apparatus, process and method, and that changes may be made therein without departing from the scope of the invention which is defined in the appended claims.

What is claimed is:

1. An apparatus for treating an object, said apparatus comprising:
a vacuum chamber in which the object is intended to be placed;
means for placing the chamber under vacuum; and
an ion bombardment device intended for treating the object, comprising an ion generator and at least one ion applicator intended to emit an ion beam;
wherein said apparatus further comprises:
a first airlock;
means for selectively placing the vacuum chamber in communication with the first airlock; and
means for placing the first airlock under vacuum,
the ion bombardment device being arranged outside of the vacuum chamber, and the ion applicator being housed in the first airlock.

2. The apparatus according to claim 1, in which the ion applicator comprises means chosen from electrostatic lenses for shaping the ion beam, a diaphragm, a shutter, a collimator, an ion-beam analyzer and an ion-beam controller.

3. The apparatus according to claim 1, in which the ion generator comprises means chosen from an ionization chamber, an electron cyclotron resonance ion source, an ion accelerator, and an ion separator.

4. The apparatus according to claim 1, in which the means for placing the chamber under vacuum comprise a primary pumping assembly comprising a rotary mechanical pump in series with a Roots blower.

5. The apparatus according to claim 1, in which the means for placing the chamber under vacuum comprise a secondary pumping assembly comprising at least one pump chosen from a diffusion pump or a turbomolecular pump.

6. The apparatus according to claim 1, in which the ion bombardment device comprise a plurality of ion applicators.

7. The apparatus according to claim 1, comprising:
a second airlock;
means for selectively placing the vacuum chamber in communication with the second airlock;
means for placing the second airlock under vacuum; and vacuum sputtering or vacuum evaporation PVD deposition means comprising:
means housed in the second airlock, notably comprising a sputtering target or a material to be evaporated with means for heating this material; and
means for injecting gas into the vacuum chamber, notably a gas intended to create a plasma, for example argon and/or a reactive gas, for example oxygen or nitrogen.

8. The apparatus according to claim 1, comprising plasma-enhanced PECVD deposition means, comprising:
at least one electrode intended to be brought to a potential different from that of the object to be treated; and
means for injecting, into the vacuum chamber, gas intended to create a plasma.

9. The apparatus according to claim 1, in which the means for placing the chamber under vacuum and the means for placing each airlock under vacuum comprise communal pumping means.

10. The apparatus according to claim 1, comprising a planetary carrier fitted in the vacuum chamber so as to be able to rotate about a virtual axis (XP) relative to this chamber, this planetary carrier preferably bearing a plurality of satellite supports for supporting objects, each satellite support being fitted so as to be able to rotate about a virtual axis (XS) relative to this planetary carrier (18).

11. The apparatus according to claim 1, in which the vacuum chamber, called the ion bombardment chamber, is housed in another vacuum chamber, called container, the means for placing the ion bombardment chamber under vacuum comprising means for indirectly generating a vacuum, connected to this ion bombardment chamber via the container chamber and, preferably, means for generating a vacuum in the ion bombardment chamber directly.

12. The apparatus according to claim 11, comprising:
at least one PVD deposition chamber housed in the container chamber;
a moveable support, intended to carry the object to be treated, which support can be moved between a position for accommodating the object in the ion bombardment chamber and a position for accommodating the object in the PVD deposition chamber;
means for placing the PVD deposition chamber under vacuum;
a second airlock;
means for selectively placing the PVD deposition chamber and the second airlock in communication;
means for placing the second airlock under vacuum; and vacuum sputtering or vacuum evaporation PVD deposition means, comprising:
means housed in the second airlock, comprising notably a sputtering target or a material to be evaporated with means for heating this material; and
means for injecting gas into the vacuum chamber, notably a gas intended to create a plasma, for example argon and/or a reactive gas, for example oxygen or nitrogen.

13. The apparatus according to claim 11, comprising:
at least one PECVD deposition chamber, housed in the container chamber, the moveable support also being able to move into a position for accommodating the object in the PECVD deposition chamber;
means for placing the PECVD deposition chamber under vacuum; and
plasma-enhanced PECVD deposition means, comprising:
at least one electrode intended to be brought to a different potential from that of the object to be treated, and
means for injecting, into the vacuum chamber, gas intended to create a plasma.

14. The apparatus according to claim 11, comprising:
at least one loading/unloading chamber for loading/unloading objects, said loading/unloading chamber being housed in the container chamber, the moveable support also being able to move into a receiving/presenting position in the loading/unloading chamber; and
means for placing the loading/unloading chamber under vacuum.

15. The apparatus according to claim 11, comprising a support fitted so as to oscillate about at least one axis (X), preferably about two substantially perpendicular axes (X, Y), and bearing the ion applicator and at least part of the ion generator so as to allow a beam to be formed that oscillates about at least one axis, preferably about two substantially perpendicular axes.

16. The use of an apparatus according to claim 1 for the treatment of an object made of polymer.

17. An apparatus for treating an object, said apparatus comprising:
a vacuum chamber in which the object is intended to be placed;
a vacuum generator for placing the chamber under vacuum; and
an ion bombardment device intended for treating the object, comprising an ion generator and at least one ion applicator intended to emit an ion beam;
wherein said apparatus further comprises:
a first airlock;
a first member for selectively placing the vacuum chamber in communication with the first airlock; and
said vacuum generator being adapted to place the first airlock under vacuum,
the ion bombardment device being arranged outside of the vacuum chamber, and the ion applicator being housed in the first airlock.

18. The apparatus according to claim 17, in which the ion applicator comprises an ion beam shaper chosen from electrostatic lenses for shaping the ion beam, a diaphragm, a shutter, a collimator, an ion-beam analyzer and an ion-beam controller.

19. The apparatus according to claim 17, in which the ion generator comprises an electron cyclotron resonance ion source, an ion accelerator, and an ion separator.

20. The apparatus according to claim 17, in which said vacuum generator for placing the chamber under vacuum comprise a primary pumping assembly comprising a rotary mechanical pump in series with a Roots blower.

21. The apparatus according to claim 17, in which said vacuum generator for placing the chamber under vacuum comprises a secondary pumping assembly comprising at least one pump chosen from a diffusion pump or a turbomolecular pump.

22. The apparatus according to claim 17, in which the ion bombardment device comprise a plurality of ion applicators.

23. The apparatus according to claim 17, comprising:
a second airlock;
a second member for selectively placing the vacuum chamber in communication with the second airlock;
said vacuum generator for placing the second airlock under vacuum; and vacuum sputtering or vacuum evaporation PVD depositor comprising:
a sputtering target or a material to be evaporated situated in said second airlock with a heater for heating this material; and
a gas injector for injecting a gas into the vacuum chamber, said gas being adapted to create a plasma, for example argon and/or a reactive gas, for example oxygen or nitrogen.

24. The apparatus according to claim 17, comprising plasma-enhanced PECVD deposition means, comprising:
at least one electrode intended to be brought to a potential different from that of the object to be treated; and
an injector for injecting, into the vacuum chamber, gas intended to create a plasma.

25. The apparatus according to claim 17, in which said vacuum generator for placing the chamber under vacuum and each airlock under vacuum comprises communal pumping means.

26. The apparatus according to claim 17, comprising a planetary carrier fitted in the vacuum chamber so as to be able to rotate about a virtual axis (XP) relative to this chamber, this planetary carrier preferably bearing a plurality of satellite supports for supporting objects, each satellite support being fitted so as to be able to rotate about a virtual axis (XS) relative to this planetary carrier (18).

27. The apparatus according to claim 17, in which the vacuum chamber, called the ion bombardment chamber, is housed in another vacuum chamber, called container, the means for placing the ion bombardment chamber under vacuum comprising means for indirectly generating a vacuum, connected to this ion bombardment chamber via the container chamber and, preferably, means for generating a vacuum in the ion bombardment chamber directly.
